(19) United States
(12) Patent Application Publication
(10) Pub. No.: US 2026/0271380 A1
(43) Pub. Date: Sep. 10, 2026

(54) SEMICONDUCTOR STRUCTURE AND MANUFACTURING METHOD THEREOF

(71) Applicant: NANYA TECHNOLOGY CORPORATION, New Taipei City (TW)

(72) Inventors: Yen-Ho Chu, New Taipei City (TW); Weng Yiang Tham, New Taipei City (TW); Cheng-Yi Hu, New Taipei City (TW)

(73) Assignee: NANYA TECHNOLOGY CORPORATION, New Taipei City (TW)

(21) Appl. No.: 19/071,731

(22) Filed: Mar. 5, 2025

(51) Int. Cl. H10D 84/83; H10D 62/832; H10D 64/01; H10D 64/66; H10D 64/68

(52) U.S. Cl. CPC H10D 84/83135; H10D 62/832; H10D 64/01; H10D 64/666; H10D 64/669; H10D 64/685; H10D 64/691; H10D 84/8311

(57) ABSTRACT

A semiconductor structure and a manufacturing method thereof are provided. The semiconductor structure includes N-type and P-type transistors separated from each other. The N-type transistor includes a first gate dielectric layer disposed on the substrate, a metal-doped region, a first gate layer and first doped regions. The metal-doped region is disposed in the first gate dielectric layer. The first gate layer is disposed on the first gate dielectric layer. The first doped regions are disposed in the substrate on two sides of the first gate layer. The P-type transistor includes a channel layer disposed on the substrate, a second gate dielectric layer, a second gate layer and second doped regions. The second gate dielectric layer is disposed on the channel layer. The second gate layer is disposed on the second gate dielectric layer. The second doped regions are disposed in the substrate on two sides of the channel layer.

### BACKGROUND

### Technical Field

The present invention relates to a semiconductor structure and a manufacturing method thereof, and in particular to a semiconductor structure including a high dielectric constant (high-k) layer and a manufacturing method thereof.

### Description of Related Art

For an N-type transistor including a high-k gate dielectric layer and a metal-containing gate, the threshold voltage (Vt) may be increased due to the metal contained in the metal-containing gate. In order to reduce the threshold voltage of the N-type transistor, some material may be doped in the high-k gate dielectric layer to form a dipole after the high-k gate dielectric layer is formed.

However, when the material is doped into the high-k gate dielectric layer of the type transistor, the high-k gate dielectric layer of the P-type transistor may be doped at the same time. As a result, the threshold voltage of the P-type transistor is changed, and thus the electrical properties of the P-type transistor are affected.

### SUMMARY

The present invention provides a semiconductor structure and a manufacturing method thereof, in which the high-k gate dielectric layer of the N-type transistor may be doped and the high-k gate dielectric layer of the P-type transistor may not be doped.

The semiconductor structure of the present invention includes an N-type transistor a a P-type transistor disposed on a substrate and separated from each other. The N-type transistor includes a first gate dielectric layer, a metal-doped region, a first gate layer and first doped regions. The first gate dielectric layer is disposed on the substrate. The metal-doped region is disposed in the first gate dielectric layer. The first gate layer is disposed on the first gate dielectric layer. The first doped regions are disposed in the substrate on two sides of the first gate layer. The P-type transistor includes a channel layer, a second gate dielectric layer, a second gate layer and second doped regions. The channel layer is disposed on the substrate. The second gate dielectric layer is disposed on the channel layer. The second gate layer is disposed on the second gate dielectric layer.

The second doped regions are disposed in the substrate on two sides of the channel layer.

In an embodiment of the semiconductor structure of the present invention, the first gat dielectric layer includes an oxide layer and a high dielectric constant layer disposed on the oxide layer, wherein the metal-doped region is located in the high dielectric constant layer of the first gate dielectric layer.

In an embodiment of the semiconductor structure of the present invention, the metal-doped region further extends into the first gate layer.

In an embodiment of the semiconductor structure of the present invention, the first gat layer includes a TiN layer.

In an embodiment of the semiconductor structure of the present invention, the metal-doped region is located throughout the high dielectric constant layer and throughout the TiN layer.

In an embodiment of the semiconductor structure of the present invention, a metal contained in the metal-doped region includes La, La₂O₃, Mg or Y.

In an embodiment of the semiconductor structure of the present invention, the first gat dielectric layer and the second gate dielectric layer are the same.

In an embodiment of the semiconductor structure of the present invention, the first gat layer and the second gate layer are the same.

In an embodiment of the semiconductor structure of the present invention, the channel layer includes an un-doped SiGe layer.

The manufacturing method of the semiconductor structure of the present invention includes the following steps. An N-type transistor and a P-type transistor are formed on a substrate and separated from each other. The N-type transistor includes a first gate dielectric layer, a metal-doped region, a first gate layer and first doped regions. The first gate dielectric layer is formed on the substrate. The metal-doped region is formed in the first gate dielectric layer. The first gate layer is formed on the first gate dielectric layer. The first doped regions are formed in the substrate on two sides of the first gate layer. The P-type transistor includes a channel layer, a second gate dielectric layer, a second gate layer and second doped regions. The channel layer is formed on the substrate. The second gate dielectric layer is formed on the channel layer. The second gate layer is formed on the second gate dielectric layer. The second doped regions are formed in the substrate on two sides of the channel layer.

In an embodiment of the manufacturing method of the semiconductor structure of the present invention, a forming method of the N-type transistor and the P-type transistor includes the following steps. The substrate having a first region and a second region is provided. The channel layer is formed in the substrate in the second region. A gate dielectric material layer is formed on the substrate. A first diffusion barrier layer is formed on the gate dielectric material layer in the second region. A metal layer is formed on the gate dielectric material layer in the first region and the first diffusion barrier layer in the second region. A second diffusion barrier layer is formed on the metal layer. A heat treatment is performed to drive a metal in the metal layer into the gate dielectric material layer in the first region to form the metal-doped region. The second diffusion barrier layer, the metal layer and the first diffusion barrier layer are removed. A gate material layer is formed on the gate dielectric material layer. A patterning process is performed on the gate material layer and the gate dielectric material layer to form the first gate layer and the first gate dielectric layer on the substrate in the first region and the second gate layer and the second gate dielectric layer on the substrate in the second region. The channel layer on both sides of the second gate layer is removed to expose a portion of the substrate. The first doped regions are formed in the substrate on two sides of the first gate layer, and the second doped regions are formed in the exposed portion of the substrate on two sides of the second gate layer.

In an embodiment of the manufacturing method of the semiconductor structure of the present invention, the gate dielectric material layer includes an oxide layer and a high dielectric constant layer formed on the oxide layer.

In an embodiment of the manufacturing method of the semiconductor structure of the present invention, the metal in the metal-doped region is further driven into the gate material layer in the first region, so that the metal-doped region further extends into the first gate layer.

In an embodiment of the manufacturing method of the semiconductor structure of the present invention, the gate material layer includes a TiN layer.

In an embodiment of the manufacturing method of the semiconductor structure of the present invention, the metal-doped region is formed throughout the high dielectric constant layer and throughout the gate material layer in the first region.

In an embodiment of the manufacturing method of the semiconductor structure of the present invention, a forming method of the N-type transistor and the P-type transistor includes the following steps. The substrate having a first region and a second region is provided. The channel layer is formed on the substrate in the second region. A gate dielectric material layer is formed on the substrate. A metal layer is formed on the gate dielectric material layer in the first region. A diffusion barrier layer is formed on the metal layer in the first region and the gate dielectric material layer in the second region. A heat treatment is performed to drive a metal in the metal layer into the gate dielectric material layer in the first region to form the metal-doped region. The diffusion barrier layer and the metal layer are removed. A gate material layer is formed on the gate dielectric material layer. A patterning process is performed on the gate material layer and the gate dielectric material layer to form the first gate layer and the first gate dielectric layer on the substrate in the first region and the second gate layer and the second gate dielectric layer on the substrate in the second region. The channel layer on both sides of the second gate layer is removed to expose a portion of the substrate. The first doped regions are formed in the substrate on two sides of the first gate layer, and the second doped regions are formed in the exposed portion of the substrate on two sides of the channel layer.

In an embodiment of the manufacturing method of the semiconductor structure of the present invention, the gate dielectric material layer includes an oxide layer and a high dielectric constant layer formed on the oxide layer.

In an embodiment of the manufacturing method of the semiconductor structure of the present invention, the metal in the metal layer is further driven into the gate material layer in the first region, so that the metal-doped region further extends into the first gate layer in the first region.

In an embodiment of the manufacturing method of the semiconductor structure of the present invention, the gate material layer includes a TiN layer.

In an embodiment of the manufacturing method of the semiconductor structure of the present invention, the metal-doped region is formed throughout the high dielectric constant layer and throughout the gate material layer in the first region.

In an embodiment of the manufacturing method of the semiconductor structure of the present invention, a metal contained in the metal-doped region includes La, La₂O₃, Mg or Y.

In an embodiment of the manufacturing method of the semiconductor structure of the present invention, the channel layer includes an un-doped SiGe layer.

Based on the above, in the manufacturing method of the semiconductor structure of the present invention, during the heat treatment, the metal in the metal layer may not be driven into the gate dielectric material layer in the second region, and is driven only into the gate dielectric material layer in the first region. Therefore, the gate dielectric material layer in the first region may be doped with the metal and the gate dielectric material layer in the second region may not be doped with the metal at the same time. In this way, the gate dielectric material layer of the N-type transistor is doped and thus includes the metal-doped region, and the gate dielectric material layer of the P-type transistor is not doped and thus does not include a metal-doped region.

### BRIEF DESCRIPTION OF THE DRAWINGS

FIGS. 1A to 1H are schematic cross-sectional views of the manufacturing method of the semiconductor structure of the first embodiment of the present invention.

FIGS. 2A to 2G are schematic cross-sectional views of the manufacturing method of the semiconductor structure of the second embodiment of the present invention.

### DESCRIPTION OF THE EMBODIMENTS

The embodiments are described in detail below with reference to the accompanying drawings, but the embodiments are not intended to limit the scope of the present invention. In addition, the drawings are for illustrative purposes only and are not drawn to the original dimensions. For the sake of easy understanding, the same elements in the following description will be denoted by the same reference numerals.

In the text, the terms mentioned in the text, such as “comprising”, “including”, “containing” and “having” are all open-ended terms, i.e., meaning “including but not limited to”.

When using terms such as “first” and “second” to describe elements, it is only used to distinguish the elements from each other, and does not limit the order or importance of the devices. Therefore, in some cases, the first element may also be called the second element, the second element may also be called the first element, and this is not beyond the scope of the present invention.

In addition, the directional terms, such as “on”, “above”, “under” and “below” mentioned in the text are only used to refer to the direction of the drawings, and are not used to limit the present invention.

Also, herein, a range expressed by “one value to another value” is a general representation to avoid enumerating all values in the range in the specification. Thus, the recitation of a particular numerical range encompasses any numerical value within that numerical range, as well as smaller numerical ranges bounded by any numerical value within that numerical range.

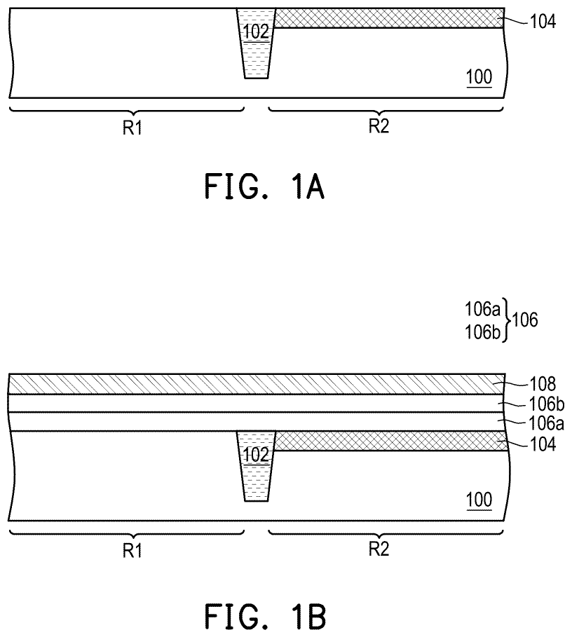

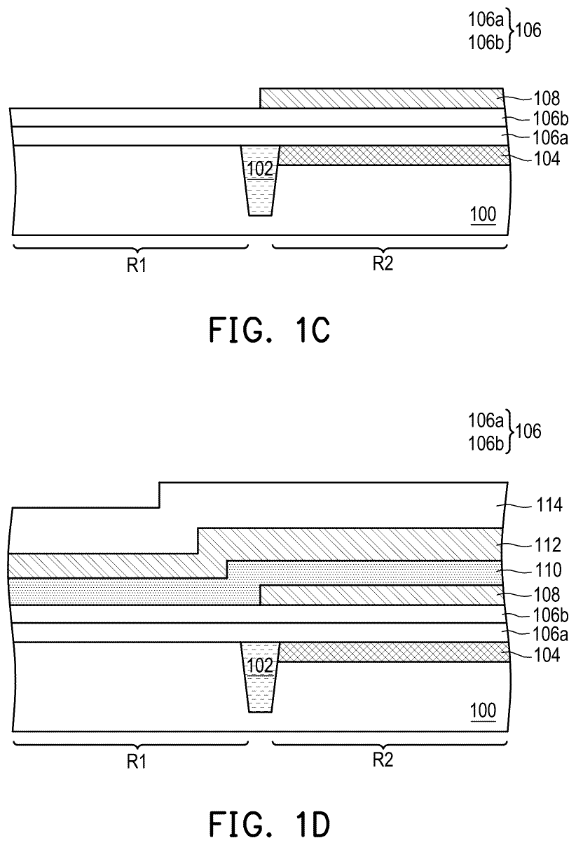

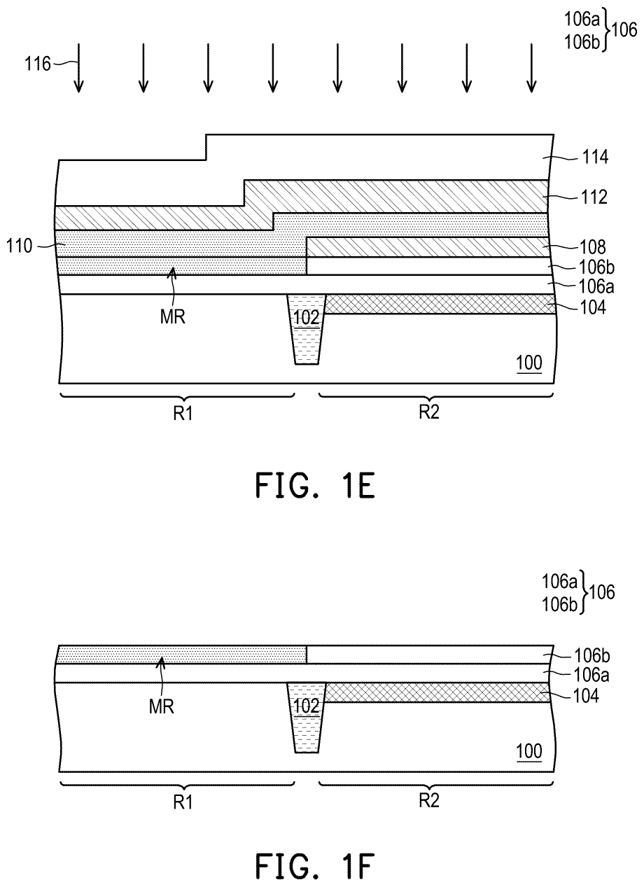

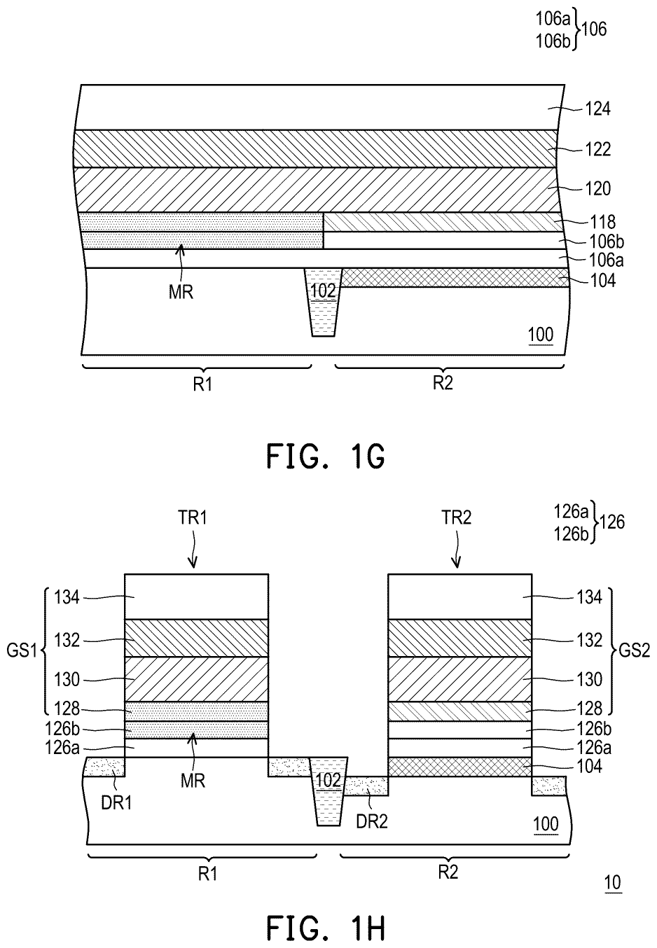

FIGS. 1A to 1H are schematic cross-sectional views of the manufacturing method of the semiconductor structure of the first embodiment of the present invention.

Referring to FIG. 1A, a substrate 100 is provided. The substrate 100 may be a silicon substrate. In the present embodiment, the substrate 100 has a first region R1 and a second region R2, wherein the first region R1 is used to form an N-type transistor and the second region R2 is used to form a P-type transistor. The first region R1 and the second region R2 are separated from each other by a device isolation structure 102. The device isolation structure 102 may be a shallow trench isolation (STI) structure, but the present invention is not limited thereto. In the present embodiment, the top surface of the device isolation structure 102 is coplanar with the top surface of the substrate 100. The method for forming the device isolation structure 102 is well known to those skilled in the art and will not be further described here.

Then, a channel layer 104 is formed in the substrate 100 in the second region R2 In the present embodiment, the channel layer 104 may be an un-doped SiGe layer, but the present invention is not limited thereto. A method for forming the channel layer 104 may include the following steps. A part of the substrate 100 in the second region R2 is removed to form a recess. Then, an epitaxially growing process is performed to form the channel layer 104 in the recess. In the present embodiment, the top surface of the channel layer 104 is coplanar with the top surface of the substrate 100 and the top surface of the device isolation structure 102.

Referring to FIG. 1B, a gate dielectric material layer 106 is formed on the substrate 100. In the present embodiment, the gate dielectric material layer 106 includes an oxide layer 106a and a high dielectric constant (high-k) layer 106b formed on the substrate 100 in sequence. Generally speaking, a high-k material generally refers to a dielectric material with a dielectric constant greater than 4 in the present technical field. The high-k material may be aluminum oxide (Al₂O₃), tantalum oxide (Ta₂O₃), titanium oxide (TiO₂), yttrium oxide (Y₂O₃), zirconium oxide (ZrO₂), hafnium oxide (HfO₂), etc., but the present invention is not limited thereto.

After the gate dielectric material layer 106 is formed, a first diffusion barrier layer 108 is formed on the gate dielectric material layer 106. The first diffusion barrier layer 108 is used to prevent metal from the outside from diffusing into the gate dielectric material layer 106, especially the high-k layer 106b. In the present embodiment, the first diffusion barrier layer 108 may be a TiN layer, a Ti layer or TiSiₓ layer, but the present invention is not limited thereto. The thickness of the first diffusion barrier layer 108 may be 2 μm to 15 μm. When the thickness of the first diffusion barrier layer 108 is less than 2 μm, the first diffusion barrier layer 108 cannot effectively prevent the metal from diffusing into the gate dielectric material layer 106. When the thickness of the first diffusion barrier layer 108 is more than 15 μm, it is difficult to remove the first diffusion barrier layer 108 in the subsequent process.

Referring to FIG. 1C, the first diffusion barrier layer 108 in the first region R1 is removed. A method for removing the first diffusion barrier layer 108 in the first region R1 may include the following steps. A mask layer covering the second region R2 is formed on the first diffusion barrier layer 108 to expose the first diffusion barrier layer 108 in the first region R1. Next, an anisotropic etching process is performed to remove the exposed first diffusion barrier layer 108 by using the mask layer as the etching mask to expose the gate dielectric material layer 106 in the first region R1. Then, the mask layer is removed.

Referring to FIG. 1D, a metal layer 110 is formed on the substrate 100. The met layer 110 covers the gate dielectric material layer 106 in the first region R1 and the first diffusion barrier layer 108 in the second region R2. In the present embodiment, the metal contained in the metal layer 110 may be La, La₂O₃, Mg or Y, but the present invention is not limited thereto. For example, the metal layer 110 may be a La layer.

After the metal layer 110 is formed, a second diffusion barrier layer 112 is formed on the metal layer 110. The second diffusion barrier layer 112 is used to prevent the metal contained in the metal layer 110 from diffusing to the outside. In the present embodiment, the second diffusion barrier layer 112 may be a TiN layer, a Ti layer or a TiSiₓ layer, but the present invention is not limited thereto. The thickness of the second diffusion barrier layer 112 may be 2 μm to 15 μm. When the thickness of the second diffusion barrier layer 112 is less than 2 μm, the second diffusion barrier layer 112 cannot effectively prevent the metal from diffusing to the outside. When the thickness of the second diffusion barrier layer 112 is more than 15 μm, it is difficult to remove the second diffusion barrier layer 112 in the subsequent process.

In addition, in the present embodiment, a capping layer 114 may be optionally formed on the second diffusion barrier layer 112 to protect the second diffusion barrier layer 112. In the present embodiment, the capping layer 114 may be an amorphous silicon (a-Si) layer, but the present invention is not limited thereto. The thickness of the capping layer 114 may be 5 μm to 100 μm.

Referring to FIG. 1E, a heat treatment 116 is performed to drive the metal in the metal layer 110 into the high-k layer 106b of the gate dielectric material layer 106 in the first region R1 to form a metal-doped region MR as a metal dipole. In the present embodiment, the metal in the metal layer 110 is driven into the entire high-k layer 106b, that is, the metal-doped region MR is formed throughout the high-k layer 106b, but the present invention is not limited thereto. In other embodiments, depending on actual needs, by adjusting the time and the temperature of the heat treatment 116, the metal in the metal layer 110 may be driven into a portion of the high-k layer 106b. For example, the metal in the metal layer 110 may be driven only into an upper portion of the high-k layer 106b.

In FIG. 1E, since the first diffusion barrier layer 108 is located in the second region R2 to cover the gate dielectric material layer 106 in the second region R2, during the heat treatment 116, the metal in the metal layer 110 may not be driven into the gate dielectric material layer 106 in the second region R2, and is driven only into the gate dielectric material layer 106 in the first region R1. In other words, during the heat treatment 116, the gate dielectric material layer 106 in the first region R1 may be doped with the metal and the gate dielectric material layer 106 in the second region R2 may not be doped with the metal at the same time.

Referring to FIG. 1F, the capping layer 114, the second diffusion barrier layer 112, the metal layer 110 and the first diffusion barrier layer 108 are removed. A method for removing the capping layer 114, the second diffusion barrier layer 112, the metal layer 110 and the first diffusion barrier layer 108 is, for example, performing an etching process or a chemical mechanical polishing (CMP) process.

Referring to FIG. 1G, a gate material layer 118 is formed on the gate dielectric material layer 106. In the present embodiment, the gate material layer 118 may be a TiN layer, a Ti layer or a TiSiₓ layer, but the present invention is not limited thereto. The thickness of the gate material layer 118 may be 2 μm to 10 μm.

In addition, additional layers may be formed on the gate material layer 118. For example, in the present embodiment, after the gate material layer 118 is formed, a first conductive material layer 120, a second conductive material layer 122 and a capping material layer 124 may be formed on the gate material layer 118 in sequence, but the present invention is not limited thereto. The first conductive material layer 120 may be a polysilicon layer. The second conductive material layer 122 may be a metal layer, such as a TiN layer, a Ti layer or a TiSiₓ layer. The capping material layer 124 may be a nitride layer.

During forming the gate material layer 118 or during the subsequent process after forming the gate material layer 118, the process temperature may drive the metal in the metal-doped region MR into the gate material layer 118 in the first region R1. In the present embodiment, the metal in the metal-doped region MR may be driven into the entire gate material layer 118 in the first region R1, that is, the metal-doped region MR may further extend into the entire gate material layer 118, but the present invention is not limited thereto. In other embodiments, depending on actual process temperature, the metal in the metal-doped region MR may be driven into a portion of the gate material layer 118 in the first region R1. For example, the metal in the metal-doped region MR may be driven only into a lower portion of the gate material layer 118 in the first region R1.

Referring to FIG. 1H, a patterning process is performed on the capping material layer 124, the second conductive material layer 122, the first conductive material layer 120, the gate material layer 118 and the gate dielectric material layer 106 to form a capping layer 134, a second conductive layer 132, a first conductive layer 130, a gate layer 128 and a gate dielectric layer 126 on the substrate 100 in the first region R1 and the second region R2, respectively.

In detail, the capping layer 134, the second conductive layer 132, the first conductive layer 130, the gate layer 128 in the first region R1 form a first gate structure GS1, and the gate dielectric layer 126 in the first region R1 includes an oxide layer 126a formed by the oxide layer 106a and a high-k layer 126b formed by the high-k layer 106b, wherein the metal-doped region MR is located throughout the high-k layer 106b and throughout the gate layer 128. In addition, the capping layer 134, the second conductive layer 132, the first conductive layer 130, the gate layer 128 in the second region R2 form a second gate structure GS2, and the gate dielectric layer 126 in the second region R2 includes an oxide layer 126a formed by the oxide layer 106a and a high-k layer 126b formed by the high-k layer 106b.

After the patterning process, first doped regions DR1 having the N-type dopants are formed in the substrate 100 on two sides of the first gate structure GS1. In addition, the channel layer 104 on both sides of the second gate structure GS2 is removed to expose a portion of the substrate 100, and then second doped regions DR2 having the P-type dopants are formed in the exposed portion of the substrate 100. In this way, the semiconductor structure 10 of the present embodiment is formed. Methods for forming the first doped regions DR1 and the second doped regions DR2 are well known to those skilled in the art and will not be further described here.

In the semiconductor structure 10, the first gate structure GS1, the gate dielectric layer 126 and the first doped regions DR1 form a N-type transistor TR1 in the first region R1, and the second gate structure GS2, the gate dielectric layer 126, the channel layer 104 and the second doped regions DR2 form a P-type transistor TR2 in the second region R2. The N-type transistor TR1 and the-type transistor TR2 are separated from each other by the device isolation structure 102. In addition, the high-k layer 126b of the N-type transistor TR1 is doped and thus includes the metal-doped region MR, and the high-k layer 126b of the P-type transistor TR2 is not doped and thus does not include a metal-doped region.

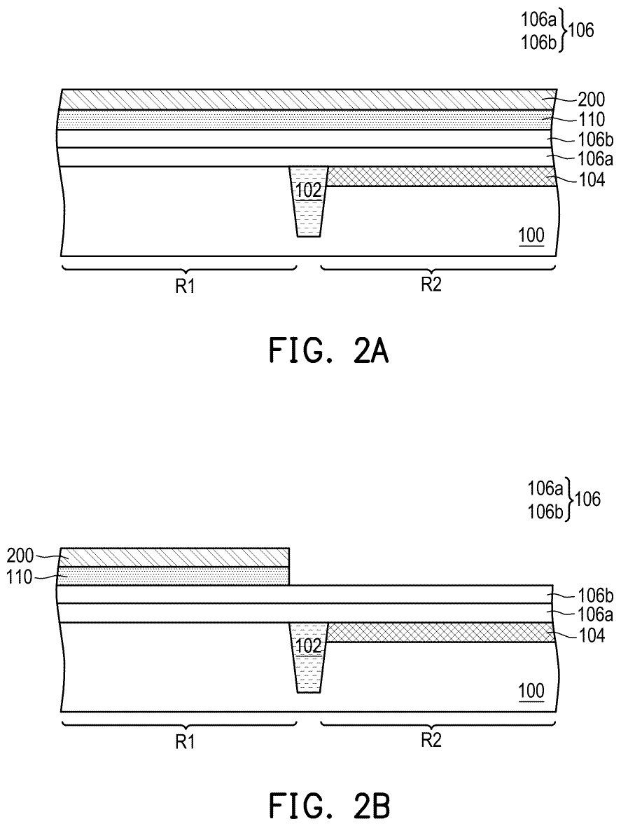

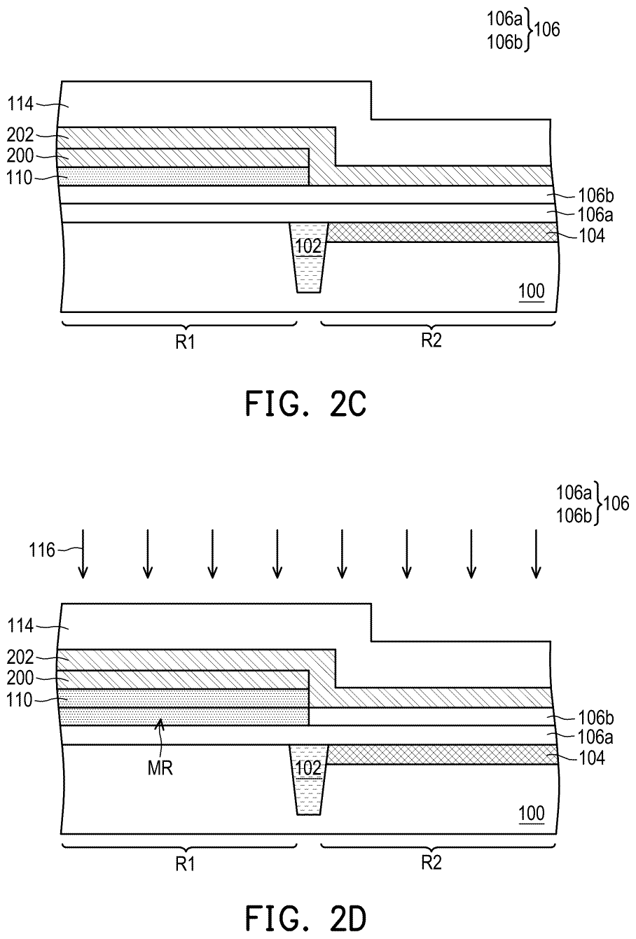

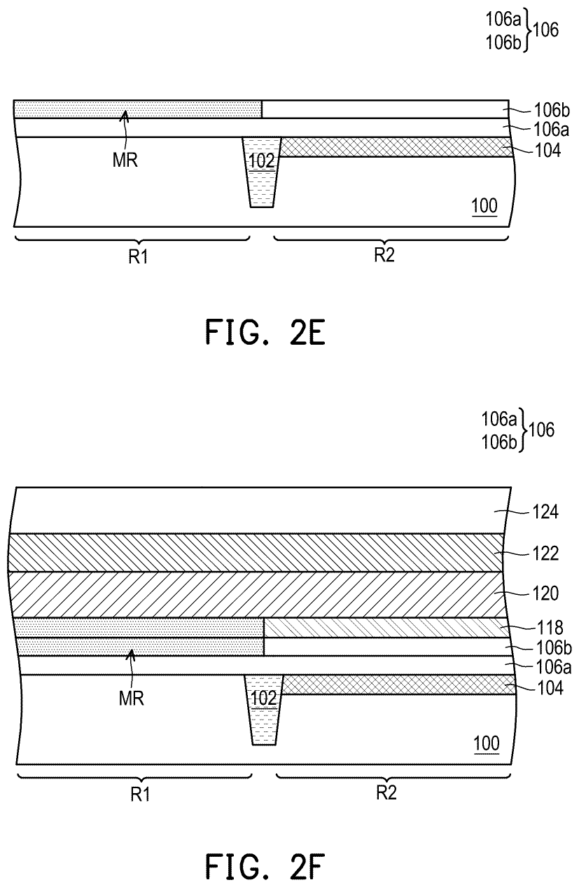

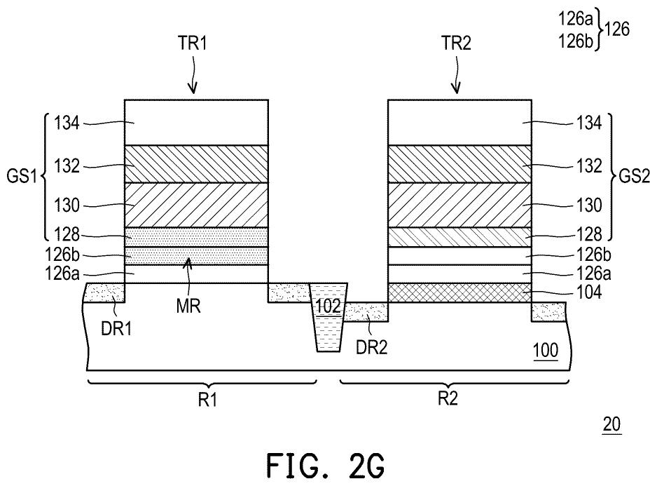

FIGS. 2A to 2G are schematic cross-sectional views of the manufacturing method of the semiconductor structure of the second embodiment of the present invention. In the present embodiment, the devices that are the same as those in the first embodiment will be represented by the same reference symbols and will not be described again.

Referring to FIG. 2A, after forming the gate dielectric material layer 106 as described in FIG. 1B, the metal layer 110 and a protection layer 200 are formed on the gate dielectric material layer 106 in sequence. The protection layer 200 is used to protect the metal layer 110. In the present embodiment, the protection layer 200 may be a TiN layer, but the present invention is not limited thereto. In addition, depending on actual needs, in other embodiments, the protection layer 200 may be omitted.

Then, the protection layer 200 and the metal layer 110 in the second region R2 are removed. A method for removing the protection layer 200 and the metal layer 110 in the second region R2 may include the following steps. A mask layer covering the first region R1 is formed on the protection layer 200 to expose the protection layer 200 in the second region R2. Next, an anisotropic etching process is performed to remove the exposed protection layer 200 and the metal layer 110 thereunder by using the mask layer as the etching mask to expose the gate dielectric material layer 106 in the second region R2. Then, the mask layer is removed.

Referring to FIG. 2C, a diffusion barrier layer 202 is formed on the substrate 100. The diffusion barrier layer 202 covers the protection layer 200 and the metal layer 110 thereunder in the first region R1 and the gate dielectric material layer 106 in the second region R2. The diffusion barrier layer 202 is used to prevent the metal contained in the metal layer 110 from diffusing to the outside. In the present embodiment, the diffusion barrier layer 202 may be a TiN layer, a Ti layer or a TiSiₓ layer, but the present invention is not limited thereto. The thickness of the diffusion barrier layer 202 may be 2 μm to 15 μm. When the thickness of the diffusion barrier layer 202 is less than 2 μm, the diffusion barrier layer 202 cannot effectively prevent the metal from diffusing to the outside. When the thickness of the diffusion barrier layer 202 is more than 15 μm, it is difficult to remove the diffusion barrier layer 202 in the subsequent process.

In addition, in the present embodiment, the capping layer 114 may be optionally formed on the diffusion barrier layer 202 to protect the diffusion barrier layer 202.

Referring to FIG. 2D, as described in FIG. 1E, the heat treatment 116 is performed to drive the metal in the metal layer 110 into the high-k layer 106b of the gate dielectric material layer 106 in the first region R1 to form the metal-doped region MR as a metal dipole. In the present embodiment, the metal in the metal layer 110 is driven into the entire high-k layer 106b, that is, the metal-doped region MR is formed throughout the high-k layer 106b, but the present invention is not limited thereto. In other embodiments, depending on actual needs, by adjusting the time and the temperature of the heat treatment 116, the metal in the metal layer 110 may be driven into a portion of the high-k layer 106b. For example, the metal in the metal layer 110 may be driven only into an upper portion of the high-k layer 106b.

In addition, in the present embodiment, since the metal layer 110 in the second region R2 is removed, during the heat treatment 116, the metal in the metal layer 110 may not be driven into the gate dielectric material layer 106 in the second region R2, and is driven only into the gate dielectric material layer 106 in the first region R1. In other words, during the heat treatment 116, the gate dielectric material layer 106 in the first region R1 may be doped with the metal and the gate dielectric material layer 106 in the second region R2 may not be doped with the metal at the same time.

Referring to FIG. 2E, the capping layer 114, the diffusion barrier layer 202, protection layer 200 and the metal layer 110 are removed. A method for removing the capping layer 114, the diffusion barrier layer 202, protection layer 200 and the metal layer 110 is, for example, performing an etching process or a CMP process.

Referring to FIG. 2F, as described in FIG. 1G, the gate material layer 118 is formed on the gate dielectric material layer 106. In addition, additional layers may be formed on the gate layer 118. For example, in the present embodiment, after the gate material layer 118 is formed, the first conductive material layer 120, the second conductive material layer 122 and the capping material layer 124 may be formed on the gate material layer 118 in sequence, but the present invention is not limited thereto.

During forming the gate material layer 118 or during the subsequent process after forming the gate material layer 118, the process temperature may drive the metal in the metal-doped region MR into the gate material layer 118 in the first region R1. In the present embodiment, the metal in the metal-doped region MR may be driven into the entire gate material layer 118 in the first region R1, that is, the metal-doped region MR may further extend into the entire gate material layer 118, but the present invention is not limited thereto. In other embodiments, depending on actual process temperature, the metal in the metal-doped region MR may be driven into a portion of the gate material layer 118 in the first region R1. For example, the metal in the metal-doped region MR may be driven only into a lower portion of the gate material layer 118 in the first region R1.

Referring to FIG. 2G, as described in FIG. 1H, a patterning process is performed on the capping material layer 124, the second conductive material layer 122, the first conductive material layer 120, the gate material layer 118 and the gate dielectric material layer 106 to form the first gate structure GS1 and the gate dielectric layer 126 in the first region R1 and to form the second gate structure GS2 and the gate dielectric layer 126 in the second region R2.

After the patterning process, first doped regions DR1 having the N-type dopants are formed in the substrate 100 on two sides of the first gate structure GS1. In addition, the channel layer 104 on both sides of the second gate structure GS2 is removed to expose a portion of the substrate 100, and then second doped regions DR2 having the P-type dopants are formed in the exposed portion of the substrate 100. In this way, the semiconductor structure 20 of the present embodiment is formed.

As the semiconductor structure 10, the semiconductor structure 20 includes the N-type transistor TR1 and the-type transistor TR2 separated from each other by the device isolation structure 102, wherein the high-k layer 126b of the N-type transistor TR1 is doped and thus includes the metal-doped region MR, and the high-k layer 126b of the P-type transistor TR2 is not doped and thus does not include a metal-doped region.

It will be apparent to those skilled in the art that various modifications and variations may be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A semiconductor structure, comprising:
an N-type transistor, disposed on a substrate, and comprising:
a first gate dielectric layer, disposed on the substrate;
a metal-doped region, disposed in the first gate dielectric layer;
a first gate layer, disposed on the first gate dielectric layer; and
first doped regions, disposed in the substrate on two sides of the first gate layer; and
a P-type transistor, disposed on the substrate, separated from the N-type transistor, and comprising:
a channel layer, disposed on the substrate;
a second gate dielectric layer, disposed on the channel layer;
a second gate layer, disposed on the second gate dielectric layer; and
second doped regions, disposed in the substrate on two sides of the channel layer.

2. The semiconductor structure of claim 1, wherein the first gate dielectric layer comprises:
an oxide layer; and
a high dielectric constant layer, disposed on the oxide layer,
wherein the metal-doped region is located in the high dielectric constant layer of the first gate dielectric layer.

3. The semiconductor structure of claim 2, wherein the metal-doped region further extends into the first gate layer.

4. The semiconductor structure of claim 3, wherein the first gate layer comprises a TiN layer, a Ti layer or a TiSiₓ layer.

5. The semiconductor structure of claim 4, wherein the metal-doped region is located throughout the high dielectric constant layer and throughout the first gate layer.

6. The semiconductor structure of claim 1, wherein a metal contained in the metal-doped region comprises La, La₂O₃, Mg or Y.

7. The semiconductor structure of claim 1, wherein the first gate dielectric layer and the second gate dielectric layer are the same.

8. The semiconductor structure of claim 1, wherein the first gate layer and the second gate layer are the same.

9. The semiconductor structure of claim 1, wherein the channel layer comprises an un-doped SiGe layer.

10. A manufacturing method of a semiconductor structure, comprising:
forming an N-type transistor on a substrate, wherein the N-type transistor comprises:
a first gate dielectric layer, formed on the substrate;
a metal-doped region, formed in the first gate dielectric layer;
a first gate layer, formed on the first gate dielectric layer; and
first doped regions, formed in the substrate on two sides of the first gate layer; and
forming a P-type transistor on the substrate, wherein the P-type transistor is separated from the N-type transistor and comprises:
a channel layer, formed on the substrate;
a second gate dielectric layer, formed on the channel layer;
a second gate layer, formed on the second gate dielectric layer; and
second doped regions, formed in the substrate on two sides of the channel layer.

11. The manufacturing method of claim 10, wherein a forming method of the N-type transistor and the P-type transistor comprises:
providing the substrate having a first region and a second region;
forming the channel layer in the substrate in the second region;
forming a gate dielectric material layer on the substrate;
forming a first diffusion barrier layer on the gate dielectric material layer in the second region;
forming a metal layer on the gate dielectric material layer in the first region and the first diffusion barrier layer in the second region;
forming a second diffusion barrier layer on the metal layer;
performing a heat treatment to drive a metal in the metal layer into the gate dielectric material layer in the first region to form the metal-doped region;
removing the second diffusion barrier layer, the metal layer and the first diffusion barrier layer;
forming a gate material layer on the gate dielectric material layer;
performing a patterning process on the gate material layer and the gate dielectric material layer to form the first gate layer and the first gate dielectric layer on the substrate in the first region and the second gate layer and the second gate dielectric layer on the substrate in the second region;
removing the channel layer on both sides of the second gate layer to expose a portion of the substrate; and
forming the first doped regions in the substrate on two sides of the first gate layer and forming the second doped regions in the exposed portion of the substrate on two sides of the second gate layer.

12. The manufacturing method of claim 11, wherein the gate dielectric material layer comprises:
an oxide layer; and
a high dielectric constant layer, formed on the oxide layer.

13. The manufacturing method of claim 12, wherein the metal in the metal-doped region is further driven into the gate material layer in the first region, so that the metal-doped region further extends into the first gate layer in the first region.

14. The manufacturing method of claim 13, wherein the gate material layer comprises a TiN layer, a Ti layer or a TiSiₓ layer.

15. The manufacturing method of claim 13, wherein the metal-doped region is formed throughout the high dielectric constant layer and throughout the gate material layer in the first region.

16. The manufacturing method of claim 10, wherein a forming method of the N-type transistor and the P-type transistor comprises:
providing the substrate having a first region and a second region;
forming the channel layer in the substrate in the second region;
forming a gate dielectric material layer on the substrate;
forming a metal layer on the gate dielectric material layer in the first region;
forming a diffusion barrier layer on the metal layer in the first region and the gate dielectric material layer in the second region;
performing a heat treatment to drive a metal in the metal layer into the gate dielectric material layer in the first region to form the metal-doped region;
removing the diffusion barrier layer and the metal layer;
forming a gate material layer on the gate dielectric material layer;
performing a patterning process on the gate material layer and the gate dielectric material layer to form the first gate layer and the first gate dielectric layer on the substrate in the first region and the second gate layer and the second gate dielectric layer on the substrate in the second region;
removing the channel layer on both sides of the second gate layer to expose a portion of the substrate; and
forming the first doped regions in the substrate on two sides of the first gate layer and forming the second doped regions in the exposed portion of the substrate on two sides of the channel layer.

17. The manufacturing method of claim 16, wherein the gate dielectric material layer comprises:
an oxide layer; and
a high dielectric constant layer, formed on the oxide layer.

18. The manufacturing method of claim 17, wherein the metal in the metal layer is further driven into the gate material layer in the first region, so that the metal-doped region further extends into the first gate layer.

19. The manufacturing method of claim 18, wherein the gate material layer comprises a TiN layer, a Ti layer or a TiSiₓ layer.

20. The manufacturing method of claim 19, wherein the metal-doped region is formed throughout the high dielectric constant layer and throughout the gate material layer in the first region.

21. The manufacturing method of claim 10, wherein a metal contained in the metal-doped region comprises La, La₂O₃, Mg or Y.

22. The manufacturing method of claim 10, wherein the channel layer comprises an un-doped SiGe layer.
